(19) United States
(12) Patent Application Publication
(10) Pub. No.: US 2026/0185226 A1
(43) Pub. Date: Jul. 2, 2026

(54) MULTIPLE SUBSTITUTED CYCLOPENTADIENYL RARE-EARTH COMPLEXES AS PRECURSORS FOR VAPOR PHASE THIN FILM DEPOSITION PROCESSES

(71) Applicants: Merck Patent GMBH, Darmstadt (DE); Versum Materials US, LLC, Tempe, AZ (US)

(72) Inventors: Lukas Mai, Darmstadt (DE); Paul Mehlmann, Darmstadt (DE); Lars Lietzau, Rossdorf (DE); Thorsten Loeffler, Darmstadt (DE); Philipp Hans Fackler, Rossdorf (DE); Holger Heil, Rossdorf (DE); Sergei V. Ivanov, Schnecksville, PA (US)

(21) Appl. No.: 19/106,733

(22) PCT Filed: Aug. 1, 2023
(86) PCT No.: PCT/US2023/071460

§ 371 Date: Feb. 26, 2025

Related U.S. Application Data
(60) Provisional application No. 63/374,124, filed on Aug. 31, 2022.

(51) Int. Cl. C23C 16/455; C07F 17/02; C23C 16/40; H10P 14/43

(52) U.S. Cl. CPC C23C 16/45553; C07F 17/02; C23C 16/40; H10P 14/43

(57) ABSTRACT

The disclosed and claimed subject matter provides precursors having at least one tethered cyclopentadienyl ligand (“Cp ligand”), at least one amidinate ligand (“Ad ligand”) and a lanthanide and/or lanthanide-like transition metal (“M”) of the general formulae (i) (Cp ligand)2-M-(Ad ligand) or (ii) (Cp ligand)-M-(Ad ligand)2.

### BACKGROUND

### Field

The disclosed and claimed subject matter relates to organometallic compounds including lanthanide and/or lanthanide-like transition metals, compositions containing the compounds and methods of using the compounds as precursors for deposition of metal-containing films.

### Related Art

Transition metal-containing films are used in semiconductor and electronics applications. Chemical Vapor Deposition (CVD) and Atomic Layer Deposition (ALD) have been applied as the main deposition techniques for producing thin films for semiconductor devices. These methods enable the achievement of conformal films (metal, metal oxide, metal nitride, metal silicide, and the like) through chemical reactions of metal-containing compounds (precursors). The chemical reactions occur on surfaces which may include metals, metal oxides, metal nitrides, metal silicides, and other surfaces. In CVD and ALD, the precursor molecule plays a critical role in achieving high quality films with high conformality and low impurities. The temperature of the substrate in CVD and ALD processes is an important consideration in selecting a precursor molecule. Higher substrate temperatures, in the range of 150 to 500 degrees Celsius (° C.), promote a higher film growth rate. The preferred precursor molecules must be stable in this temperature range. The preferred precursor is capable of being delivered to the reaction vessel in a liquid phase. Liquid phase delivery of precursors generally provides a more uniform delivery of the precursor to the reaction vessel than solid phase precursors.

In ALD, thin films can be deposited by the reaction of a metalorganic precursor with a co-reactant, separated by inert gas purges. Due to that unique mechanism ALD is able to coat three dimensional (3D) surfaces with an atomic precision which renders it indispensable for the semiconductor industry.

U.S. Pat. No. 8,283,201 discloses precursor compounds having a cyclopentadienyl ligand having at least one aliphatic group as a substituent and an amidine ligand. In particular, the disclosed structures include lanthanide-containing precursors of the formula Ln(R¹Cp)ₘ(R²—N—C(R⁴)=N—R²)ₙ where (i) Ln is a lanthanide metal having an ionic radius from approximately 0.75 Å to approximately 0.94 Å, a 3+ charge, and a coordination number of 6, (ii) R¹ is selected from the group consisting of H and a C₁-C₅ alkyl chain, (iii) R² is selected from the group consisting of H and a C₁-C₅ alkyl chain, (iv) R⁴ is selected from the group consisting of H and Me, (v) n and m range from 1 to 2 and (vi) the precursor has a melting point below approximately 105° C.

U.S. Patent Application Publication No. 2019/0152996 (U.S. patent application Ser. No. 16/251,236) discloses a lanthanum-containing compound of the following formula

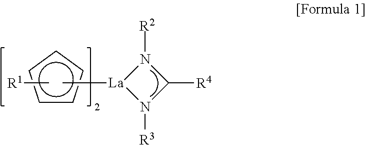

where R¹ is a hydrogen atom or a C₁-C₄ linear or branched alkyl group, R² and R³ are each independently a hydrogen atom or a C1-C5 linear or branched alkyl group, at least one of R² and R³ being a C3-C5 branched alkyl group, and R⁴ is a hydrogen atom or a C1-C4 linear or branched alkyl group. In this regard, during prosecution of this application, the USPTO acknowledged that U.S. Pat. No. 8,283,201 fails to teach or suggest an asymmetrical amidinate where R² and R³ are different from one another.

There is a need in the art for thermally stable lanthanide and/or lanthanide-like organometallic compounds suitable as CVD and ALD precursors that can be preferably delivered in liquid phase, have low impurities and can produce a high-quality film with high conformality.

In this regard, common for rare-earth (RE) precursors for ALD often employ THD (2,2,6,6-tetramethyl-3,5-heptandionate), different cyclopentadienyl ligands (“Cp ligand” or “Cp”) and amidinate ligands (“Ad ligand” or “AMD”). In case of La, for example, the precursors La(iPr-Cp)₃ (tris-isopropylcyclopentadienyl lanthanum(III)), La(iPr₂-FAMD)₃(tris-diisopropylformamidinate lanthanum(III)) and the heteroleptic La(iPr-Cp)₂(iPr₂-MeAMD) (bis(isopropylcyclopentadienyl)(diisopropylacetamidinate) lanthanum(III)) can be regarded as benchmark precursors. La(iPr-Cp)₃ is a volatile, thermally stable, low melting solid with poor reactivity. A good reactivity combined with high volatility for La precursors can be found in La(iPr₂-FAMD). However, it has no melting point and is less stable compared to La(iPr-Cp)₃ which is a drawback in terms of evaporation behavior and application in ALD. Thus, the combination of stable iPr-Cp ligands with reactive amidinates was used to obtain the heteroleptic precursor La(iPr-Cp)₂(iPr₂-MeAMD), which is a liquid at room temperature, however, with a poor volatility as compared to the La(iPr₂-FAMD). Approaches to increase the volatility of such compounds were made by modification of the amidinate, employing asymmetric alkyl substitution patterns on the ligand.

Notably, no attempts have been made to use asymmetric substitution on the Cp ring, even though this asymmetry might have a larger influence on the volatility, melting point and thermal stability. The disclosed and claimed subject matter provides such materials.

### SUMMARY

The disclosed and claimed subject matter provides precursors having at least one tethered cyclopentadienyl ligand (“Cp ligand”), at least one amidinate ligand (“Ad ligand”) and a lanthanide and/or lanthanide-like transition metal (“M”) of the general formulae (i) (Cp ligand)₂-M-(Ad ligand) or (ii) (Cp ligand)-M-(Ad ligand)₂. The disclosed and claimed subject matter further includes compositions containing the compounds, methods of using the compounds as precursors for deposition of metal-containing films and films derived from the precursors.

In one embodiment, the precursor having at least one tethered cyclopentadienyl ligand and at least one amidinate ligand has Formula I:

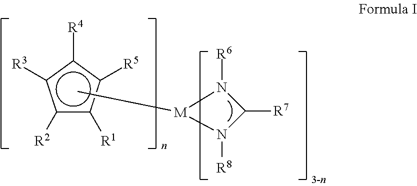

where
   (i) M is one of La, Sc, Y, Ce, Pr, Nd, Pm, Sm, Eu, Gd, Tb, Dy, Ho, Er, Tm, Yb and Lu;
   (ii) R¹, R², R³, R⁴ and R⁵ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃,
      where (a) R¹, R², R³, R⁴ and R⁵ comprise at least three different substituents and (b) at least two of R¹, R², R³, R⁴ and R⁵ are H;
   (iii) R⁶, R⁷ and R⁸ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃;
   (iv) n=1 or 2; and
   (v) the precursor is liquid below about 80° C.
      Thus, precursors of Formula I includes compounds of formulae (i) (Cp ligand)₂-M-(Ad ligand) when n=2 and (ii) (Cp ligand)-M-(Ad ligand)₂ when n=1. More specific aspects and embodiments of precursors of Formula I, (Cp ligand)₂-M-(Ad ligand) and (Cp ligand)-M-(Ad ligand)₂, respectively, are detailed below.

Without being bound by theory, it is believed that the asymmetric substitution of the Cp rings with at least two different alkyl chains results in a highly asymmetric complex. Due to that asymmetry, the melting point will be low and the volatility increased.

The disclosed and claimed subject further includes (i) compositions and formulations that include the disclosed and claimed precursors, (ii) methods of using the disclosed and claimed precursors in deposition processes and (iii) metal-containing films derived from the disclosed and claimed precursors produced in deposition processes.

### BRIEF DESCRIPTION OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates the thermogravimetric analysis (TGA) of Comparative Example 1, La(iPr-Me-Cp)₃;

FIG. 2 illustrates the ¹H NMR of Synthetic Example 1, La(iPr-Me-Cp)₂(iPr₂-FAMD);

FIG. 3 illustrates the TGA of Synthetic Example 1, La(iPr-Me-Cp)₂(iPr₂-FAMD); and

FIG. 4 illustrates the differential scanning calorimetry analysis (DSC) of Synthetic Example 1, La(iPr-Me-Cp)₂(iPr₂-FAMD).

FIG. 5 illustrates thermal decomposition of La(iPr-Me-Cp)₂(iPr₂-FAMD) precursor on Si wafers;

FIG. 6 illustrates the dependence of lanthanum oxide film thickness on Si and SiO₂ wafer vs. pulse time of La(iPr-Me-Cp)₂(iPr₂-FAMD) precursor in atomic layer deposition process; and

FIG. 7 illustrates cross-section TEM of structured wafers with lanthanum oxide films deposited using La(iPr-Me-Cp)₂(iPr₂-FAMD) precursor at 175 and 275° C.

### DETAILED DESCRIPTION

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope of the disclosed and claimed subject matter unless otherwise claimed. No language in the specification should be construed as indicating any non-claimed element as essential to the practice of the disclosed and claimed subject matter. The use of the term “comprising” or “including” in the specification and the claims includes the narrower language of “consisting essentially of” and “consisting of.”

Embodiments of the disclosed and claimed subject matter are described herein, including the best mode known to the inventors for carrying out the disclosed and claimed subject matter. Variations of those embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, the disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

It will be understood that the term “silicon” as deposited as a material on a microelectronic device will include polysilicon.

For ease of reference, “microelectronic device” or “semiconductor device” corresponds to semiconductor wafers having integrated circuits, memory, and other electronic structures fabricated thereon, and flat panel displays, phase change memory devices, solar panels and other products including solar substrates, photovoltaics, and microelectromechanical systems (MEMS), manufactured for use in microelectronic, integrated circuit, or computer chip applications. Solar substrates include, but are not limited to, silicon, amorphous silicon, polycrystalline silicon, monocrystalline silicon, CdTe, copper indium selenide, copper indium sulfide, and gallium arsenide on gallium. The solar substrates may be doped or undoped. It is to be understood that the term “microelectronic device” or “semiconductor device” is not meant to be limiting in any way and includes any substrate that will eventually become a microelectronic device or microelectronic assembly.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, and other refractory metals and their nitrides and silicides.

“Substantially free” is defined herein as less than 0.001 wt. %. “Substantially free” also includes 0.000 wt. %. The term “free of” means 0.000 wt. %. As used herein, “about” or “approximately” are intended to correspond to within ±5% of the stated value.

In all such compositions, wherein specific components of the composition are discussed in reference to weight percentage (or “weight %”) ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all percentages of the components are weight percentages and are based on the total weight of the composition, that is, 100%. Any reference to “one or more” or “at least one” includes “two or more” and “three or more” and so on.

Where applicable, all weight percents unless otherwise indicated are “neat” meaning that they do not include the aqueous solution in which they are present when added to the composition. For example, “neat” refers to the weight % amount of an undiluted acid or other material (i.e., the inclusion 100 g of 85% phosphoric acid constitutes 85 g of the acid and 15 grams of diluent).

Moreover, when referring to the compositions described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the formulation can contain 2% by weight or less of impurities. In another embodiment, the formulation can contain 1% by weight or less than of impurities. In a further embodiment, the formulation can contain 0.05% by weight or less than of impurities. In other such embodiments, the constituents can form at least 90 wt %, more preferably at least 95 wt %, more preferably at least 99 wt %, more preferably at least 99.5 wt %, most preferably at least 99.9 wt %, and can include other ingredients that do not material affect the performance of the wet etchant. Otherwise, if no significant non-essential impurity component is present, it is understood that the composition of all essential constituent components will essentially add up to 100 weight %.

The headings employed herein are not intended to be limiting; rather, they are included for organizational purposes only.

### EXEMPLARY EMBODIMENTS

One aspect of the disclosed and claimed subject matter pertains to precursors having at least one tethered cyclopentadienyl ligand (“Cp ligand”), at least one amidinate ligand (“Ad ligand”) and a lanthanide and/or lanthanide-like transition metal (“M”) of general formulae (i) (Cp ligand)₂-M-(Ad ligand) or (ii) (Cp ligand)-M-(Ad ligand)₂.

One aspect of the disclosed and claimed subject matter pertains to precursors having at least two tethered cyclopentadienyl ligands (“Cp ligand”) and at least one amidinate ligand (“Ad ligand”) of general formula (Cp ligand)₂-M-(Ad ligand) where M is one of La, Sc, Y, Ce, Pr, Nd, Pm, Sm, Eu, Gd, Tb, Dy, Ho, Er, Tm, Yb and Lu. In one aspect of this embodiment M is one of Sc, Y, La and Ce. In one aspect of this embodiment M is Sc. In one aspect of this embodiment M is Y. In one aspect of this embodiment M is La. In one aspect of this embodiment M is Ce.

One aspect of the disclosed and claimed subject matter pertains to precursors having at least one tethered cyclopentadienyl ligand (“Cp ligand”) at least two amidinate ligand (“Ad ligand”) of general formulae (Cp ligand)-M-(Ad ligand)₂, where M is one of La, Sc, Y, Ce, Pr, Nd, Pm, Sm, Eu, Gd, Tb, Dy, Ho, Er, Tm, Yb and Lu. In one aspect of this embodiment M is one of Sc, Y, La and Ce. In one aspect of this embodiment M is Sc. In one aspect of this embodiment M is Y. In one aspect of this embodiment M is La. In one aspect of this embodiment M is Ce.

In some embodiments, the tethered Cp ligand is derived from a structure illustrated in Table 1 and the tethered Ad ligand has a structure as illustrated in Table 2, below.

TABLE 1
Cp Structure

| | |
|---|---|
| 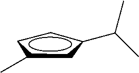 | 1A |
| 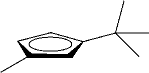 | 1B |
| 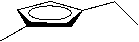 | 1C |
| 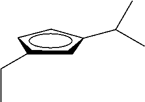 | 1D |
| 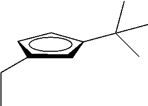 | 1E |
| 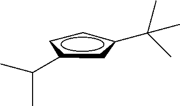 | 1F |
| 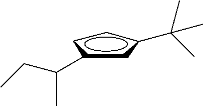 | 1G |
| 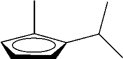 | 1H |
| 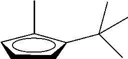 | 1I |
| 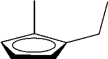 | 1J |
| 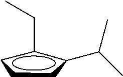 | 1K |
| 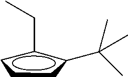 | 1L |
| 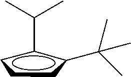 | 1M |
| 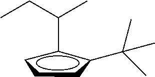 | 1N |
| 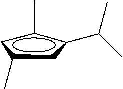 | 1O |
| 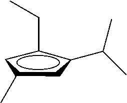 | 1P |
| 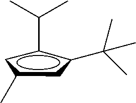 | 1Q |
| 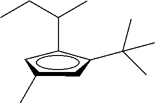 | 1R |
| 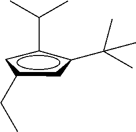 | 1S |
| 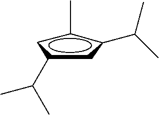 | 1T |
| 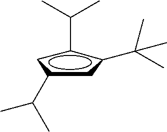 | 1U |

TABLE 2
Amidinate Structure

| | |
|---|---|
| 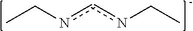 | 2A |
| 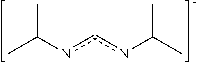 | 2B |
| 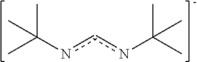 | 2C |
| 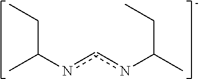 | 2D |
| 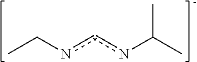 | 2E |
| 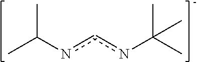 | 2F |
| 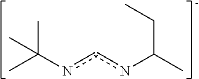 | 2G |
| 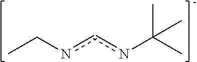 | 2H |
| 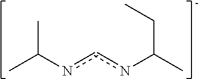 | 2I |
| 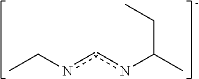 | 2J |
| 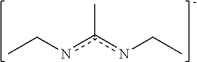 | 2K |
| 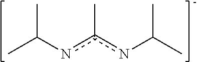 | 2L |
| 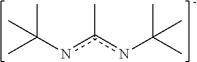 | 2M |
| 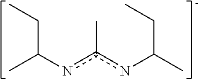 | 2N |
| 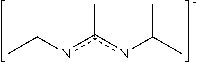 | 2O |
| 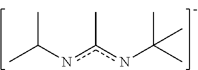 | 2P |
| 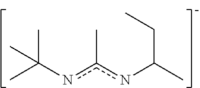 | 2Q |
| 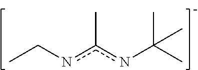 | 2R |
| 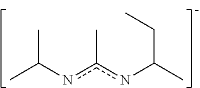 | 2S |
| 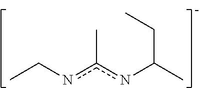 | 2T |

Preferred embodiments of general formulae (i) (Cp ligand)₂-M-(Ad ligand) and (ii) (Cp ligand)-M-(Ad ligand)₂ that include the ligands set forth in Tables 1 and 2 are described in Tables 3 and 4:

TABLE 3

| Formula | Compound |
|---|---|
| (1A)₂-M-(2B) | 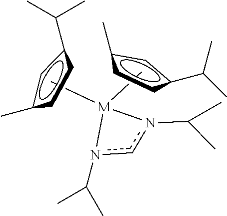 |
| (1C)₂-M-(2B) | 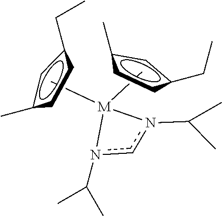 |
| (1D)₂-M-(2B) | 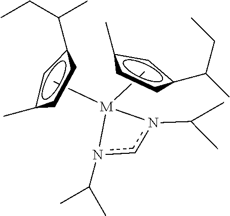 |
| (1F)₂-M-(2B) | 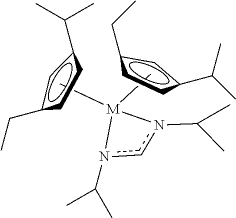 |
| (1E)_{2S}-M-(2B) | 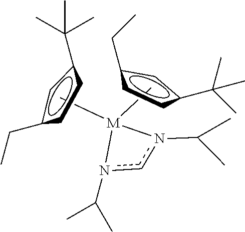 |
| (1H)₂-M-(2B) | 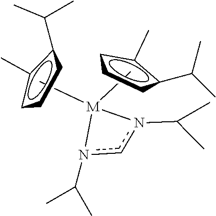 |
| (1I)₂-M-(2B) | 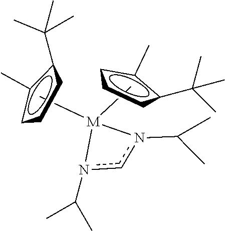 |
| (1J)₂-M-(2B) | 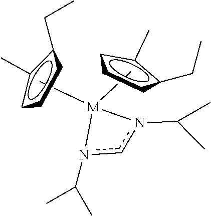 |
| (1A)₂-M-(2L) | 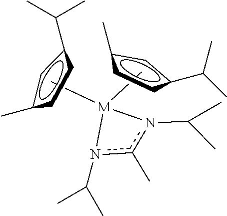 |
| (1D)₂-M-(2L) | 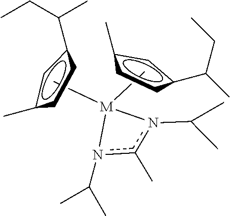 |
| (1C)₂-M-(2L) | 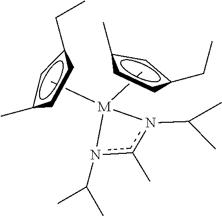 |
| (1F)₂-M-(2L) | 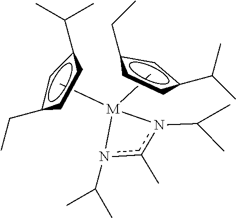 |
| (1E)₂-M-(2L) | 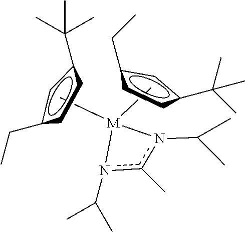 |
| (1H)₂-M-(2L) | 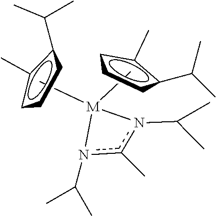 |
| (1I)₂-M-(2L) | 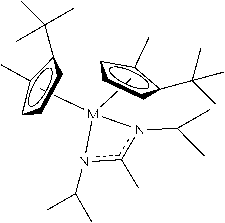 |
| (1J)₂-M-(2L) | 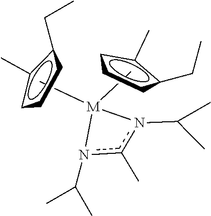 |
| (1A)₂-M-(2H) | 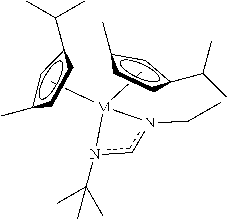 |
| (1D)₂-M-(2H) | 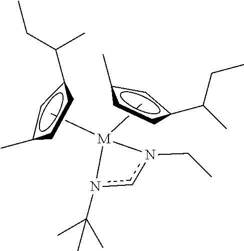 |
| (1C)₂-M-(2H) | 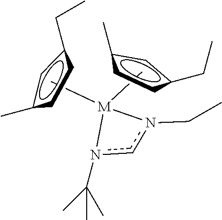 |
| (1O)₂-M-(2L) | 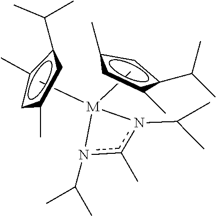 |
| (1Q)₂-M-(2B) | 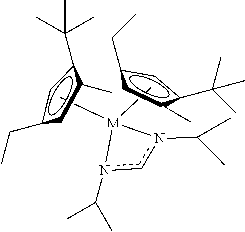 |
| (1H)₂-M-(2H) | 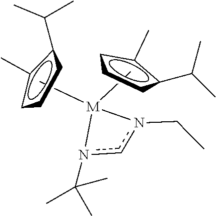 |
| (1I)₂-M-(2R) | 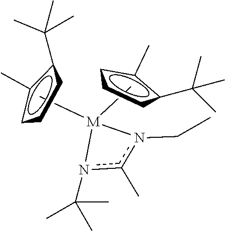 |
| (1J)₂-M-(2H) | 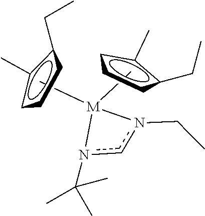 |
| (1B)₂-M-(2B) | 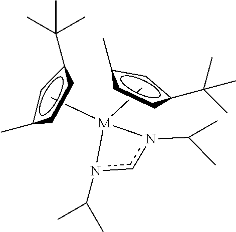 |
| (1B)₂-M-(2H) | 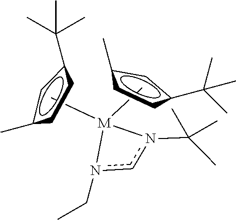 |

TABLE 4

| Formula | Compound |
|---|---|
| (1A)-M-(2B)₂ | 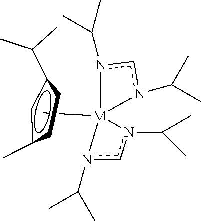 |
| (1C)-M-(2B)₂ | 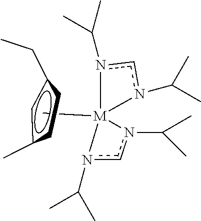 |
| (1D)-M-(2B)₂ | 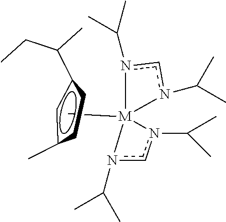 |
| (1F)-M-(2B)₂ | 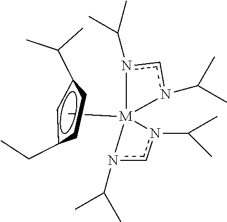 |
| (1E)-M-(2B)₂ | 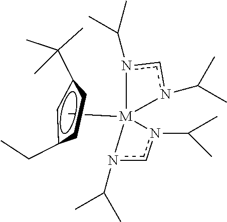 |
| (1H)-M-(2B)₂ | 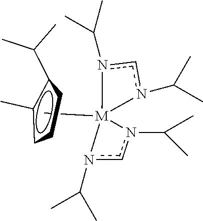 |
| (1I)-M-(2B)₂ | 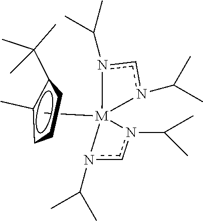 |
| (1J)-M-(2B)₂ | 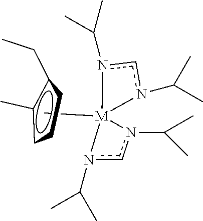 |
| (1A)-M-(2L)₂ | 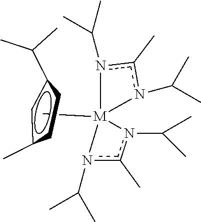 |
| (1D)-M-(2L)₂ | 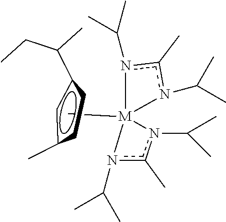 |
| (1C)-M-(2L)₂ | 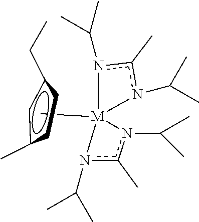 |
| (1F)-M-(2L)₂ | 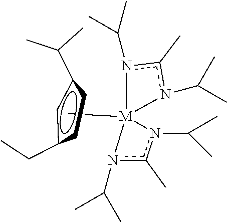 |
| (1E)-M-(2L)₂ | 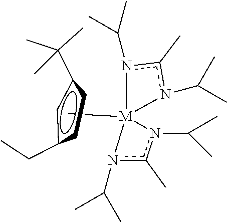 |
| (1H)-M-(2L)₂ | 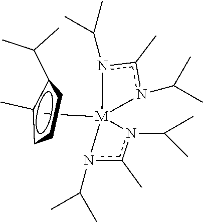 |
| (1I)-M-(2L)₂ | 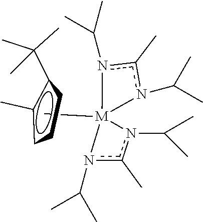 |
| (1J)-M-(2L)₂ | 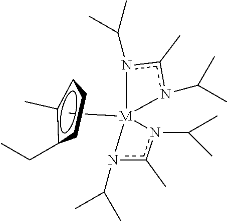 |
| (1A)-M-(2H)₂ | 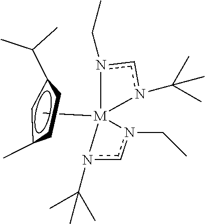 |
| (1D)-M-(2H)₂ | 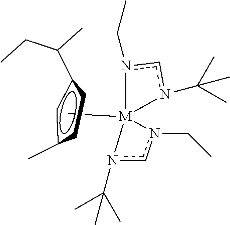 |
| (1C)-M-(2H)₂ | 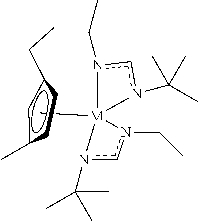 |
| (1O)-M-(2L)₂ | 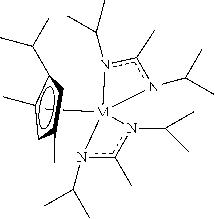 |
| (1Q)-M-(2B)₂ | 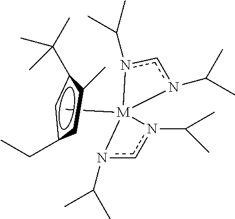 |
| (1H)-M-(2H)₂ | 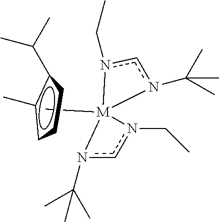 |
| (1I)-M-(2R)₂ | 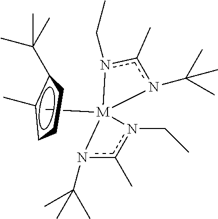 |
| (1J)-M-(2H)₂ | 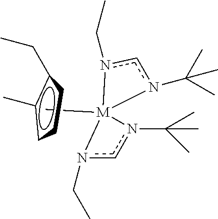 |
| (1B)-M-(2B)₂ | 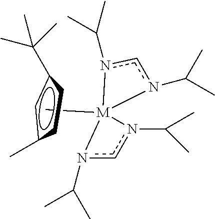 |
| (1B)-M-(2H)₂ | 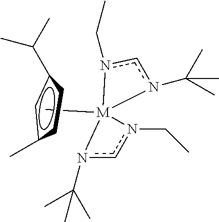 |

The disclosed and claimed precursors are not limited to those exemplified in Tables 3 and 4. In addition, the Cp ligands and Ad ligands are not limited to those exemplified in Tables 1 and 2. Additional embodiments of the disclosed and claimed precursors are described below by reference to Formula I.

### Formula I Embodiments

Embodiments and aspects thereof of precursors having at least one tethered cyclopentadienyl ligand and at least one amidinate ligand having Formula Iare exemplified as follows. As noted above, precursors of Formula I include compounds of general formulae (i) (Cp ligand)₂-M-(Ad ligand) and (ii) (Cp ligand)-M-(Ad ligand)₂ where the Cp has at least 3 different substituents

In one embodiment, the precursor having at least one tethered cyclopentadienyl ligand and at least one amidinate ligand has Formula I:

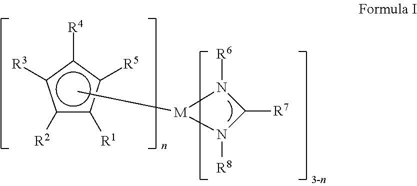

where
   (i) M is one of La, Sc, Y, Ce, Pr, Nd, Pm, Sm, Eu, Gd, Tb, Dy, Ho, Er, Tm, Yb and Lu;
   (ii) R¹, R², R³, R⁴ and R⁵ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃,
      where (a) R¹, R², R³, R⁴ and R⁵ comprise at least three different substituents and (b) at least two of R¹, R², R³, R⁴ and R⁵ are H;
   (iii) R⁶, R⁷ and R⁸ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃;
   (iv) n=1 or 2; and
   (v) the precursor is liquid below about 80° C.

In one aspect of this embodiment M is one of Sc, Y, La and Ce. In one aspect of this embodiment, M is La. In another aspect of this embodiment, M is Sc. In another aspect of this embodiment, M is Y. In another aspect of this embodiment, M is Ce. In another aspect of this embodiment, M is Pr. In another aspect of this embodiment, M is Nd. In another aspect of this embodiment, M is Pm. In another aspect of this embodiment, M is Sm. In another aspect of this embodiment, M is Eu. In another aspect of this embodiment, M is Gd. In another aspect of this embodiment, M is Tb. In another aspect of this embodiment, M is Dy. In another aspect of this embodiment, M is Ho. In another aspect of this embodiment, M is Er. In another aspect of this embodiment, M is Tm. In another aspect of this embodiment, M is Yb. In another aspect of this embodiment, M is Lu. Preferably, M is La.

In one aspect of this embodiment, R¹, R², R³, R⁴, R⁵, R⁶, R⁷ and R⁸ are each independently selected from H, an unsubstituted linear C₁-C₅ linear alkyl group and an unsubstituted branched C₃-C₆ alkyl group.

In one aspect of this embodiment, three of R¹, R², R³, R⁴ and R⁵ are H. In one aspect of this embodiment, two of R¹, R², R³, R⁴ and R⁵ are H.

In one aspect of this embodiment, one or more of R⁵, R⁶ and R⁸ is an isopropyl group. In another aspect of this embodiment, two or more of R⁵, R⁶ and R⁸ is an isopropyl group. In another aspect of this embodiment, each of R⁵, R⁶ and R⁸ is an isopropyl group.

In one aspect of this embodiment, n=1. In another aspect of this embodiment, n=2.

In one embodiment, R¹, R⁶ and R⁸ are each an isopropyl group, R³ is a methyl group and R², R⁴, R⁵ and R⁷ are each hydrogen. In one aspect of this embodiment, M=La. In one aspect of this embodiment, n=1. In another aspect of this embodiment, n=2. In a preferred aspect of this embodiment, M=La, R¹, R⁶ and R⁸ are each an isopropyl group, R³ is a methyl group and R², R⁴, R⁵ and R⁷ are each hydrogen and n=2 as follows:

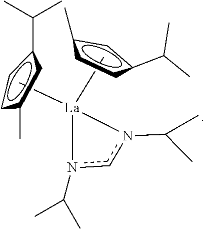

In one embodiment, R¹ is a tertbutyl group, R³ is a methyl group; R², R⁴, R⁵ are each hydrogen; R⁶ and R⁸ are each an isopropyl group and R⁷ is hydrogen. In one aspect of this embodiment, M=La. In one aspect of this embodiment, n=1. In another aspect of this embodiment, n=2. In a preferred aspect of this embodiment, M=La; R¹ is a tertbutyl group; R³ is a methyl group; R², R⁴, R⁵ are each hydrogen; R⁶ and R⁸ are each an isopropyl group; R⁷ is hydrogen; and n=2 as follows:

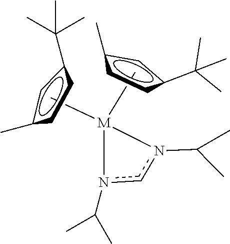

In one embodiment, R¹, R⁶ and R⁸ are each an isopropyl group, R³ and R⁷ are each a methyl group and R², R⁴ and R⁵ are each hydrogen. In one aspect of this embodiment, M=La. In one aspect of this embodiment, n=1. In another aspect of this embodiment, n=2. In a preferred aspect of this embodiment, M=La, R¹, R⁶ and R⁸ are each an isopropyl group, R³ and R⁷ are each a methyl group and R², R⁴ and R⁵ are each hydrogen and n=2 as follows:

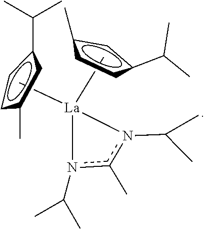

In one embodiment, R¹ is a sec-butyl group, R³ is a methyl group, R⁶ and R⁸ are each an isopropyl group, and R², R⁴, R⁵ and R⁷ are each hydrogen. In one aspect of this embodiment, M=La. In one aspect of this embodiment, n=1. In another aspect of this embodiment, n=2. In a preferred aspect of this embodiment, M=La, R¹ is a sec-butyl group, R³ is a methyl group, R⁶ and R⁸ are each an isopropyl group, and R², R⁴, R⁵ and R⁷ are each hydrogen and n=2 as follows:

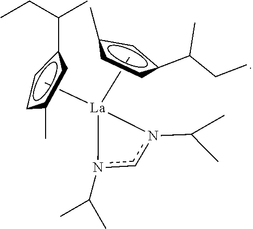

In one embodiment, R¹ is an isopropyl group, R³ is a methyl group, R⁶ is an ethyl group and R⁸ is a tertbutyl group, and R², R⁴, R⁵ and R⁷ are each hydrogen. In one aspect of this embodiment, M=La. In one aspect of this embodiment, n=1. In another aspect of this embodiment, n=2. In a preferred aspect of this embodiment, M=La, R¹ is an isopropyl group, R³ is a methyl group, R⁶ is an ethyl group and R⁸ is a tertbutyl group and R², R⁴, R⁵ and R⁷ are each hydrogen and n=2 as follows:

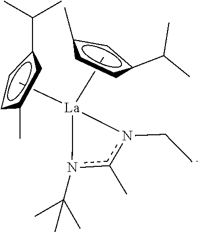

In one embodiment, R¹ is an ethyl group, R³ is a methyl group, R⁶ and R⁸ are each an isopropyl group and R², R⁴, R⁵ and R⁷ are each hydrogen. In one aspect of this embodiment, M=La. In one aspect of this embodiment, n=1. In another aspect of this embodiment, n=2. In a preferred aspect of this embodiment, M=La, R¹ is an ethyl group, R³ is a methyl group, R⁶ and R⁸ are each an isopropyl group and R², R⁴, R⁵ and R⁷ are each hydrogen and n=2 as follows:

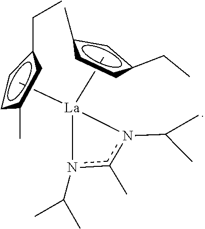

In one embodiment, R¹ and R⁶ are each an ethyl group, R³ is a methyl group, R⁸ is a tert-butyl group and R², R⁴, R⁵ and R⁷ are each hydrogen. In one aspect of this embodiment, M=La. In one aspect of this embodiment, n=1. In another aspect of this embodiment, n=2. In a preferred aspect of this embodiment, M=La, R¹ and R⁶ are each an ethyl group, R³ is a methyl group, R⁸ is a tert-butyl group and R², R⁴, R⁵ and R⁷ are each hydrogen and n=2 as follows:

### Method of Use

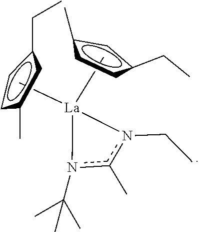

The disclosed precursors may be deposited to form lanthanide-containing films using any chemical vapor deposition process known to those of skill in the art. As used herein, the term “chemical vapor deposition process” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous,” it is understood that the precursors can be either liquid or solid which are transported with or without an inert gas into the reactor via direct vaporization, bubbling or sublimation. In some case, the vaporized precursors can pass through a plasma generator. The term “reactor” as used herein, includes without limitation, reaction chamber, reaction vessel or deposition chamber.

Chemical vapor deposition processes in which the disclosed and claimed precursors can be utilized include, but are not limited to, those used for the manufacture of semiconductor type microelectronic devices such as ALD, CVD, pulsed CVD, plasma enhanced ALD (PEALD) and/or plasma enhanced CVD (PECVD). Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the metal containing films are deposited via atomic layer deposition (ALD), plasma enhanced ALD (PEALD) or plasma enhanced cyclic CVD (PECCVD) process.

In one embodiment, for example, the metal-containing film is deposited using an ALD process. In another embodiment, the metal-containing film is deposited using a CCVD process. In a further embodiment, the metal-containing film is deposited using a thermal CVD process.

Suitable substrates on which the disclosed and claimed precursors can be deposited are not particularly limited and vary depending on the final use intended. For example, the substrate may be chosen from oxides such as HfO₂ based materials, TiO₂ based materials, ZrO₂ based materials, rare earth oxide-based materials, ternary oxide-based materials, etc. or from nitride-based films. Other substrates may include solid substrates such as metal substrates (for example, Au, Pd, Rh, Ru, W, Al, Ni, Ti, Co, Pt and metal silicides (e.g., TiSi₂, CoSi₂, and NiSi₂); metal nitride containing substrates (e.g., TaN, TiN, WN, TaCN, TiCN, TaSiN, and TiSiN); semiconductor materials (e.g., Si, SiGe, GaAs, InP, diamond, GaN, and SiC); insulators (e.g., SiO₂, Si₃N₄, SiON, HfO₂, Ta₂O₅, ZrO₂, TiO₂, Al₂O₃, and barium strontium titanate); combinations thereof. Preferred substrates include TiN, Ru and Si type substrates.

In such deposition methods and processes an oxidizing agent can be utilized. The oxidizing agent is typically introduced in gaseous form. Examples of suitable oxidizing agents include, but are not limited to, oxygen gas, water vapor, ozone, oxygen plasma, or mixtures thereof.

The deposition methods and processes may also involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, and mixtures thereof. For example, a purge gas such as Ar is supplied into the reactor at a flow rate ranging from about 10 to about 2000 sccm for about 0.1 to 10000 seconds, thereby purging the unreacted material and any byproduct that may remain in the reactor.

The deposition methods and processes require that energy be applied to the at least one of the precursors, oxidizing agent, other precursors or combination thereof to induce reaction and to form the metal-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In some processes, a secondary RF frequency source can be used to modify the plasma characteristics at the substrate surface. When utilizing plasma, the plasma-generated process may include a direct plasma-generated process in which plasma is directly generated in the reactor, or alternatively a remote plasma-generated process in which plasma is generated outside of the reactor and supplied into the reactor.

When utilized in such deposition methods and processes suitable precursors-such as those presently disclosed and claimed—may be delivered to the reaction chamber such as a CVD or ALD reactor in a variety of ways. In some instances, a liquid delivery system may be utilized. In other instances, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. The precursor compositions described herein can be effectively used as source reagents via direct liquid injection (DLI) to provide a vapor stream of these metal precursors into an ALD or CVD reactor.

When used in these deposition methods and processes, the disclosed and claimed precursors include hydrocarbon solvents which are particularly desirable due to their ability to be dried to sub-ppm levels of water. Exemplary hydrocarbon solvents that can be used in the precursors include, but are not limited to, toluene, mesitylene, cumene (isopropylbenzene), p-cymene (4-isopropyl toluene), 1,3-diisopropylbenzene, octane, dodecane, 1,2,4-trimethylcyclohexane, n-butylcyclohexane, and decahydronaphthalene (decalin). The disclosed and claimed precursors can also be stored and used in stainless steel containers. In certain embodiments, the hydrocarbon solvent is a high boiling point solvent or has a boiling point of 100° C. or greater. The disclosed and claimed precursors can also be mixed with other suitable metal precursors, and the mixture used to deliver both metals simultaneously for the growth of a binary metal-containing films.

A flow of argon and/or other gas may be employed as a carrier gas to help deliver a vapor containing at least one of the disclosed and claimed precursors to the reaction chamber during the precursor pulsing. When delivering the precursors, the reaction chamber process pressure is between 1 and 50 torr, preferably between 5 and 20 torr.

Substrate temperature can be an important process variable in the deposition of high-quality metal-containing films. Typical substrate temperatures range from about 150° C. to about 550° C. Higher temperatures can promote higher film growth rates.

In view of the forgoing, those skilled in the art will recognize that the disclosed and claimed subject matter further include the use of the disclosed and claimed precursors in Chemical vapor deposition processes as follows.

In one embodiment, the disclosed and claimed subject matter includes a method for forming a transition metal-containing film on at least one surface of a substrate that includes the steps of:
a. providing the at least one surface of the substrate in a reaction vessel;
b. forming a transition metal-containing film on the at least one surface by a deposition process chosen from a chemical vapor deposition (CVD) process and an atomic layer deposition (ALD) process using one of the disclosed and claimed precursors of as a metal source compound for the deposition process.

In a further aspect of this embodiment, the method includes introducing at least one reactant into the reaction vessel. In a further aspect of this embodiment, the method includes introducing at least one reactant into the reaction vessel where the at least one reactant is selected from the group of water, diatomic oxygen, oxygen plasma, ozone, NO, N₂O, NO₂, carbon monoxide, carbon dioxide and combinations thereof. In another aspect of this embodiment, the method includes introducing at least one reactant into the reaction vessel where the at least one reactant is selected from the group of ammonia, hydrazine, monoalkylhydrazine, dialkylhydrazine, nitrogen, nitrogen/hydrogen, ammonia plasma, nitrogen plasma, nitrogen/hydrogen plasma, and combinations thereof. In another aspect of this embodiment, the method includes introducing at least one reactant into the reaction vessel where the at least one reactant is selected from the group hydrogen, hydrogen plasma, a mixture of hydrogen and helium, a mixture of hydrogen and argon, hydrogen/helium plasma, hydrogen/argon plasma, boron-containing compounds, silicon-containing compounds and combinations thereof.

In one embodiment, the disclosed and claimed subject matter includes a method of forming a transition metal-containing film via an atomic layer deposition (ALD) process or ALD-like process that includes the steps of:
a. providing a substrate in a reaction vessel;
b. introducing into the reaction vessel one or more of the disclosed and claimed precursors;
c. purging the reaction vessel with a first purge gas;
d. introducing into the reaction vessel a source gas;
e. purging the reaction vessel with a second purge gas;
f. sequentially repeating steps b through e until a desired thickness of the transition metal-containing film is obtained.

In a further aspect of this embodiment, the source gas is one or more of an oxygen-containing source gas selected from water, diatomic oxygen, oxygen plasma, ozone, NO, N₂O, NO₂, carbon monoxide, carbon dioxide and combinations thereof. In another aspect of this embodiment, the source gas is one or more of a nitrogen-containing source gas selected from ammonia, hydrazine, monoalkylhydrazine, dialkylhydrazine, nitrogen, nitrogen/hydrogen, ammonia plasma, nitrogen plasma, nitrogen/hydrogen plasma and mixture thereof. In a further aspect of this embodiment, the first and second purge gases are each independently selected one or more of argon, nitrogen, helium, neon, and combinations thereof. In a further aspect of this embodiment, the method further includes applying energy to at least one of the precursor, the source gas, the substrate, and combinations thereof, wherein the energy is one or more of thermal, plasma, pulsed plasma, helicon plasma, high density plasma, inductively coupled plasma, X-ray, e-beam, photon, remote plasma methods and combinations thereof. In a further aspect of this embodiment, step b of the method further includes introducing into the reaction vessel the precursor using a stream of carrier gas to deliver a vapor of the precursor into the reaction vessel. In a further aspect of this embodiment, step b of the method further includes use of a solvent medium comprising one or more of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

In another embodiment, the precursors having at least one tethered cyclopentadienyl ligands and at least one amidinate ligands with Formula I can be used as a dopant for metal containing films, such as but not limited to, metal oxide films or metal nitride films. In these embodiments, the metal containing film is deposited using an ALD, ALD-like or CVD process such as those processes described herein using metal alkoxide, metal amide, or volatile organometallic precursors. Examples of suitable metal alkoxide precursors that may be used with the method disclosed herein include, but are not limited to, group 3 to 13 metal alkoxide, group 3 to 13 metal complexes having both alkoxy and alkyl substituted cyclopentadienyl ligands, group 3 to 6 metal complexes having both alkoxy and alkyl substituted pyrrolyl ligands, group 3 to 13 metal complexes having both alkoxy and diketonate ligands; group 3 to 13 metal complexes having alkyl ligands. Exemplary Group 3 to 13 metals herein include, but not limited to, Y, La, Ce, Pr, Nd, Sm, Eu, Gd, Tb, Dy, Er, Yb, Lu, Ti, Hf, Zr, V, Nb, Ta, Cr, Mo, W, Co, Ru and Al.

Examples of suitable metal amide precursors that may be used with the method disclosed herein include, but are not limited to, tetrakis(dimethylamino)zirconium (TDMAZ), tetrakis(diethylamino)zirconium (TDEAZ), tetrakis(ethylmethylamino)zirconium (TEMAZ), tris(dimethylamino)(cyclopentadienyl)zirconium, tetrakis(dimethylamino)hafnium (TDMAH), tetrakis(diethylamino)hafnium (TDEAH), and tetrakis(ethylmethylamino)hafnium (TEMAH), tris(dimethylamino)(cyclopentadienyl)hafnium, tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten, and combinations thereof. Examples of suitable organometallic precursors that may be used with the method disclosed herein include, but are not limited to, group 3 metal cyclopentadienyls or alkyl cyclopentadienyls.

Examples of suitable metal complexes having alkyl ligands that may be used with the method disclosed herein include, but are not limited to, tritertbutylaluminum (TTBA), trimethylaluminum (TMA), triethylaluminum (TEA), dimethylaluminum hydride (DMAH), dimethylethylaminealane (DMEAA), trimethylaminealane (TEAA), N-methylpyrroridine-alane (MPA), tri-isobutylaluminum (TIBA).

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods:

All solvents and starting materials were purchased from Sigma-Aldrich unless otherwise indicated. Tris-(1-isopropyl-3-methylcyclopentadienyl) lanthanum (III) [La(iPr-Me-Cp)₃] was prepared in-house. La(iPr₂-FAMD)₃ was used as purchased from STREM.

### Comparative Example 1: Synthesis of La(iPr-Me-Cp)₃

Tris-trimethylsilylamide lanthanum(III) (La(HMDS)₃) (8.2 g, 13 mmol) was suspended in 30 mL of toluene. An excess of 1-isopropyl-3-methylcyclopentadiene (iPr-Me-CpH) (11.1 g, 91 mmol) was added to the suspension. The mixture was stirred at 80° C. for 5 days. The solvent and volatile by-products were removed under reduced pressure from the mixture and the crude product was distilled in vacuum (260° C., 2×10⁻² mbar). Yield 54%

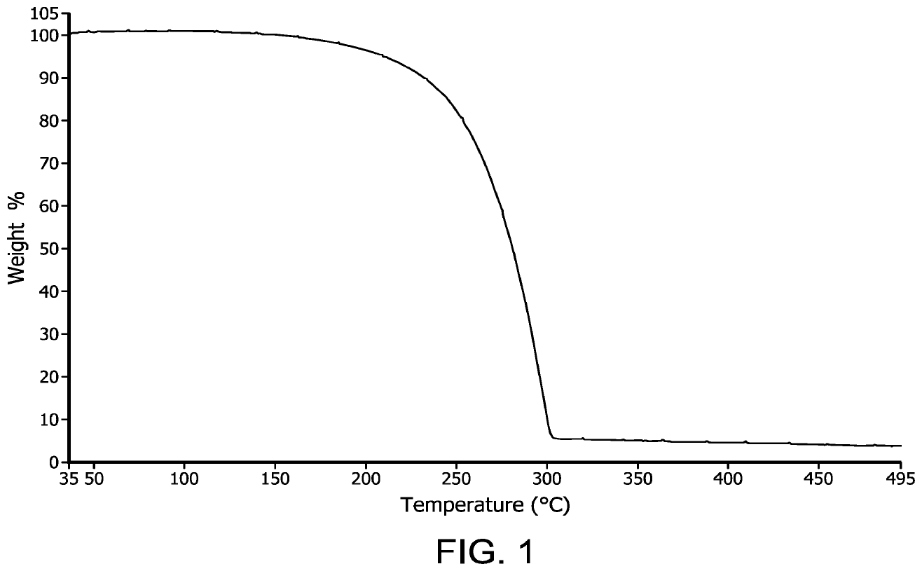

Characterization: ¹H NMR (500 MHz, C₆D₆) δ 6.00-5.78 (m, 9H), 2.85-2.67 (m, 3H), 2.13-2.05 (m, 9H), 1.20-1.09 (m, 19H).; TGA: Melting point 55° C.; Initial mass: 4.478 mg; T_{50%}=280.1° C., see FIG. 1.

### Synthetic Example 1: Synthesis of La(iPr-Me-Cp)₂(iPr₂-FAMD)

Tris-(1-isopropyl-3-methylcyclopentadienyl) lanthanum (III) [La(iPr-Me-Cp)₃](1.35 g, 2.69 mmol) was dissolved in 15 mL of toluene. Tris-(diisopropylformamidinate) lanthanum (III) [La(iPr₂-FAMD)₃](0.699 g, 1.34 mmol) was dissolved in another 15 mL of toluene and the two solutions were combined and stirred for 72 h at 100° C. The solvent was removed from the mixture and the crude product was distilled (90° C., 2×10⁻² mbar) to produce 1.38 g of a yellow liquid product. Yield: 67.5%.

Characterization: ¹H NMR (500 MHz, C6D6) δ 6.04 (dt, J=9.6, 2.8 Hz, 2H), 6.00 (q, J=2.8 Hz, 2H), 5.92 (dt, J=15.9, 2.8 Hz, 2H), 3.06 (hept, J=6.5 Hz, 2H), 2.91 (heptd, J=6.9, 3.2 Hz, 2H), 2.18 (d, J=2.9 Hz, 6H), 1.26 (dd, J=7.0, 4.3 Hz, 12H), 1.08 (d, J=6.4 Hz, 12H); TGA: initial mass: 8.720 mg, T_{50%}=254.9° C.; DSC: onset endothermic effect: 365° C.

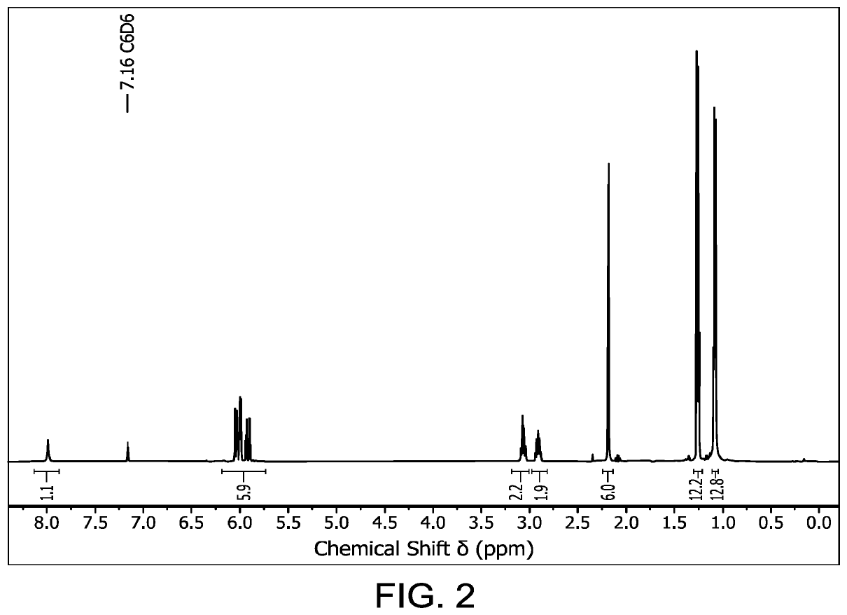

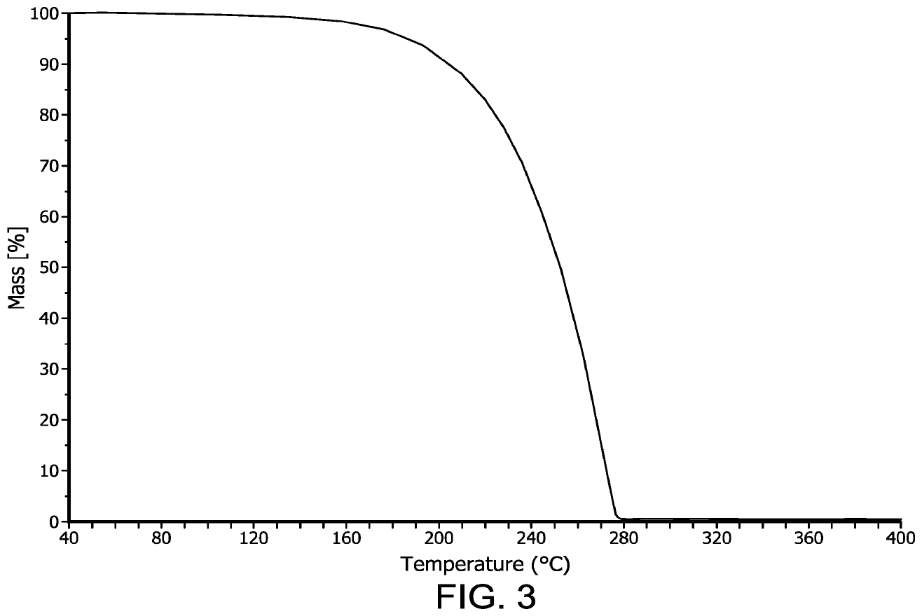

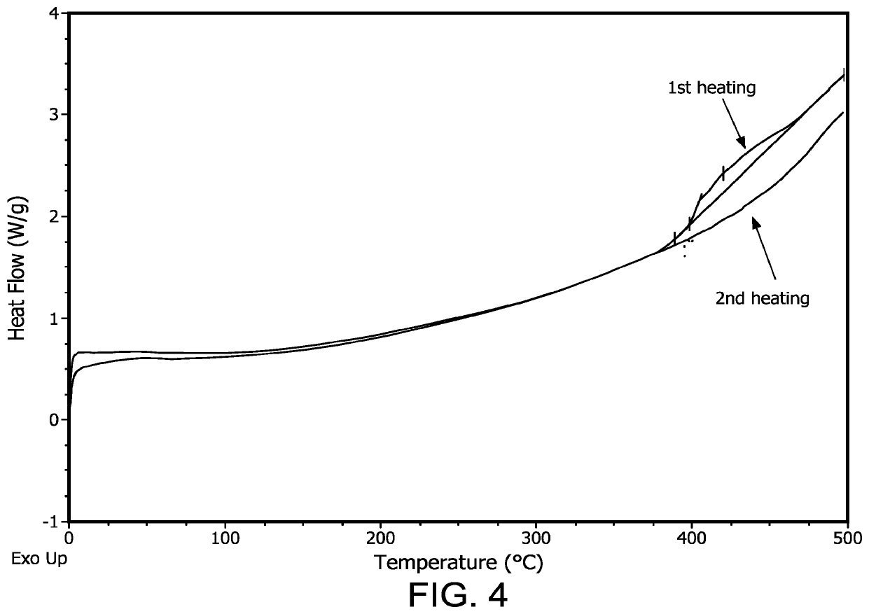

Notably, the product remained a liquid after distillation. As shown in FIG. 2, the NMR shows a clean product. The TGA shows clean evaporation which indicates a good volatility and the DSC shows good thermal stability up to 365° C. (wth no melting point could be detected between −100° C. and 365° C.). See FIGS. 3 and 4, respectively.

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

### Synthetic Example 2: Synthesis of La(tBu-Me-Cp)₂(iPr₂-FAMD)

Tris-(1-tertbutyl-3-methylcyclopentadienyl) lanthanum (III) [La(tBu-Me-Cp)₃](588.5 mg, 1.08 mmol) was dissolved in 15 mL of toluene. Tris-(diisopropylformamidinate) lanthanum (III) [La(iPr₂-FAMD)₃](281.2 mg, 0.54 mmol) was dissolved in another 15 mL of toluene and the two solutions were combined and stirred for 72 h at 100° C. The solvent was removed from the mixture and the crude product was distilled (90° C., 2×10⁻² mbar) to produce 240 mg of a yellow liquid product. Yield: 27.6%.

Characterization: ¹H NMR (500 MHz, C₆D₆) δ 8.00 (d, J=3.3 Hz, 1H), 6.15 (dt, J=12.8, 2.8 Hz, 2H), 6.10 (dt, J=9.8, 2.6 Hz, 2H), 5.89 (dt, J=29.6, 2.9 Hz, 2H), 3.10 (hept, J=6.4 Hz, 2H), 2.21 (d, J=8.5 Hz, 6H), 1.32 (d, J=9.2 Hz, 18H), 1.12 (dd, J=6.5, 3.7 Hz, 12H). TGA: initial mass: 9.6460 mg, T_{50%}=273.7° C.; DSC: onset endothermic effect: 390° C.

Notably, the product remained a liquid after distillation. The NMR shows a clean product. The TGA shows clean evaporation which indicates a good volatility and the DSC shows good thermal stability up to 390° C. (no melting point could be detected between −50° C. and 365° C.).

ALD of Lanthanum Oxide Films with La(iPr-Me-Cp)₂(iPr₂-FAMD)

An Atomic Premium CN-1 200 mm reactor was employed to demonstrate atomic layer deposition of lanthanum oxide films with the precursors of this invention. The precursor, La(iPr-Me-Cp)₂(iPr₂-FAMD), was delivered from SS316 ampoule (container) kept at 130° C. (ampoule wall temperature). 50 sccm of argon carrier gas flow was used to deliver precursor vapor to the reactor chamber. Reactor chamber pressure was 1 torr. Si and SiO₂ substrates were used to deposit lanthanum oxide films. Lanthanum oxide film thickness was measured by ellipsometry and X-ray fluorescence (XRF) calibrated using cross-section SEM images of the deposited lanthanum oxide films.

### Example 3: Precursor Thermal Decomposition Test on Si Wafer

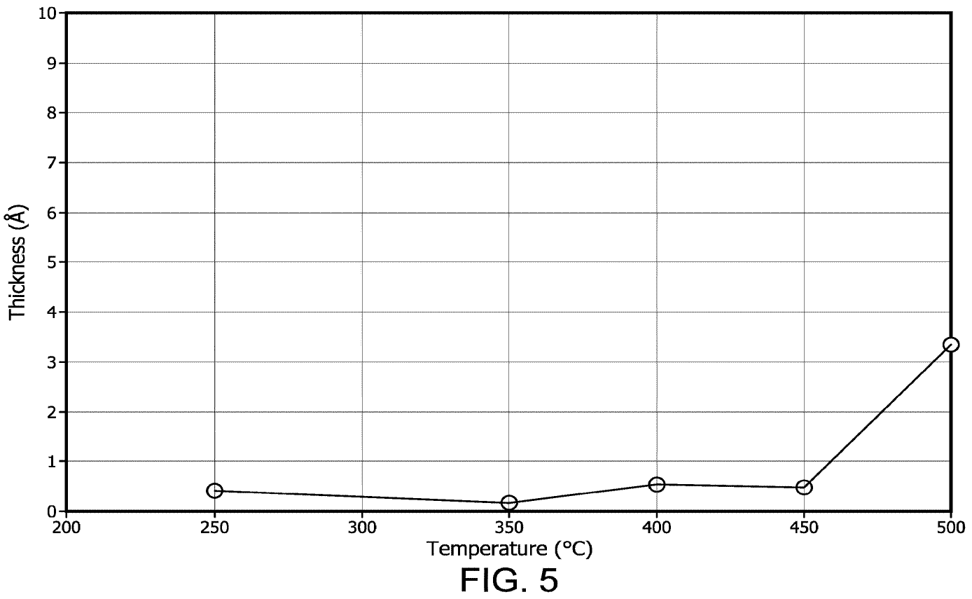

In this experiment precursor vapors were delivered to the deposition chamber in a pulsed mode separated by argon purge. Pulse sequence was: 5 sec precursor pulse and 20 sec of argon purge. The total number of precursor/Ar purge cycles was 100. No oxidant pulse was used in this experiment to demonstrate good thermal stability of the precursor in the absence of the oxidant. Good thermal stability (lack of deposition in the absence of oxidant) is important precursor property for atomic layer deposition process. Wafer temperature was varied from 200 to 450° C. After the experiment lanthanum layer density on the surface was measured by X-Ray fluorescence analysis and is shown in FIG. 5. No increase in lanthanum concentration on the silicon wafer was observed up to at least 450° C. suggesting very good thermal stability of this precursor in the vapor phase and its utility for vapor deposition applications.

### Example 4: Precursor Saturation Behavior During Deposition Process

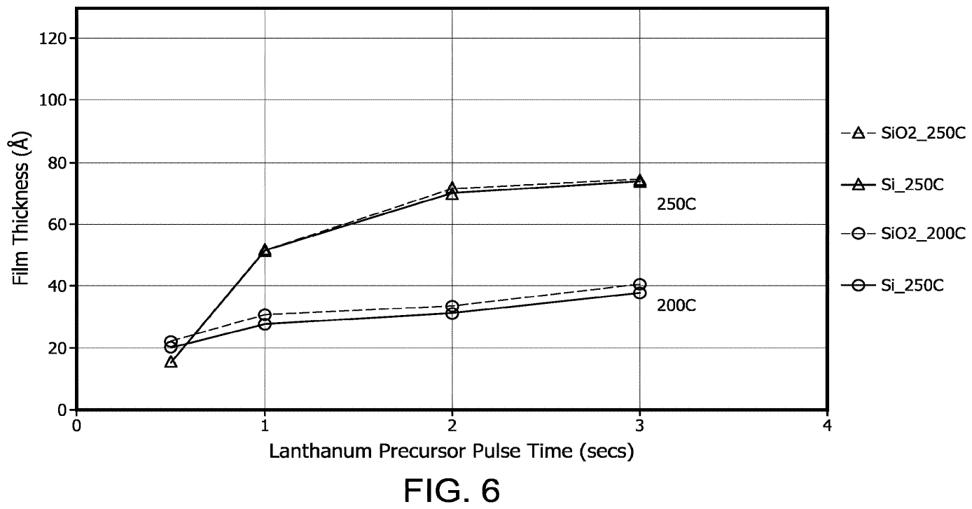

In this experiment lanthanum oxide films were deposited by atomic layer deposition method comprising the following steps:
a. providing Si or SiO₂ substrate in a reaction vessel;
b. introducing into the reaction vessel La(iPr-Me-Cp)₂(iPr₂-FAMD) precursor;
c. purging the reaction vessel with argon;
d. introducing into the reaction vessel ozone;
e. purging the reaction vessel with argon; and
f. sequentially repeating steps b through e until a desired thickness of the transition metal-containing film is obtained.
   Lanthanum precursor pulse varied from 0.5 to 3 seconds to demonstrate saturation behavior with increasing pulse time. Ar purge after precursor pulse was 10 sec, ozone pulse was 1 second, and Ar purge after precursor pulse was 30 sec. The number of ALD cycles was 100. FIG. 6 shows very good saturation behavior at 200 and 250° C. temperature. Saturation behavior is one of the key features of atomic layer deposition process.

### Example 5: Deposition of Lanthanum Oxide Film

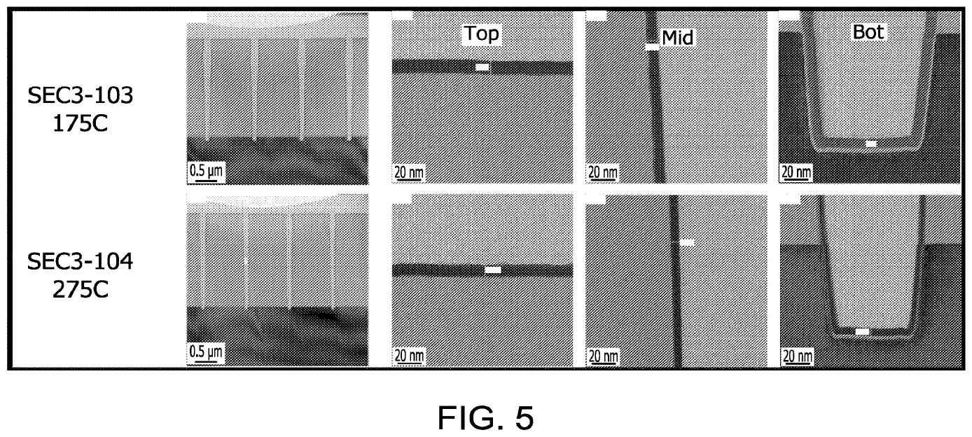

In this experiment lanthanum oxide films were deposited by atomic layer deposition method comprising the following steps:
a. providing Si or SiO₂ substrate in a reaction vessel;
b. introducing into the reaction vessel La(iPr-Me-Cp)₂(iPr₂-FAMD) precursor;
c. purging the reaction vessel with argon;
d. introducing into the reaction vessel ozone;
e. purging the reaction vessel with argon; and
f. sequentially repeating steps b through e until a desired thickness of the transition metal-containing film is obtained.
   Lanthanum precursor pulse was 3 seconds. Ar purge after precursor pulse was 30 sec, ozone pulse was 1 second, and Ar purge after precursor pulse was 30 sec. The number of ALD cycles was 100. Wafer temperature was 175 and 275° C. The FIG. 7 shows cross section TEM image of lanthanum oxide film deposited on structured wafer at 175 and 275° C. Table 5 shows film thickness on top, middle and bottom of the trench of the patterned wafer. TEM shows deposition of smooth and dense films. The experiment also shows only minor change in step coverage between 175 and 275° C. suggesting good ALD behavior. Without being bound by theory it is believed that step coverage could be further improved by process optimization, such as for example longer precursor pulse time.

TABLE 5

| | Dep | EM-1394 | TEM | TEM | TEM | % | % |
|---|---|---|---|---|---|---|---|
| Coupon | Temp | Pulse | Top Thk | Mid Thk | Bot Thk | Coverage | Coverage |
| ID | (° C.) | (secs) | (A) | (A) | (A) | Mid | Bot |
| SEC3-103 | 175 | 3 | 120 | 94 | 90 | 78.3 | 75.0 |
| SEC3-104 | 275 | 3 | 104 | 75 | 71 | 72.1 | 68.3 |

The foregoing description is intended primarily for purposes of illustration. Although the disclosed and claimed subject matter has been shown and described with respect to an exemplary embodiment thereof, it should be understood by those skilled in the art that the foregoing and various other changes, omissions, and additions in the form and detail thereof may be made therein without departing from the spirit and scope of the disclosed and claimed subject matter.

1. A transition metal precursor comprising a cyclopentadienyl ligand and an amidinate ligand of Formula I: 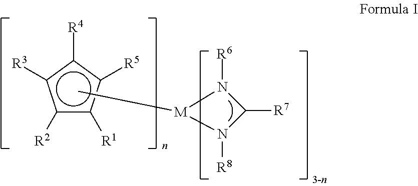
wherein
(i) M is one of La, Sc, Y, Ce, Pr, Nd, Pm, Sm, Eu, Gd, Tb, Dy, Ho, Er, Tm, Yb and Lu;
ii) in the cyclopentadienyl ligand R¹, R², R³, R⁴ and R⁵ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃, wherein (a) R¹, R², R³, R⁴ and R⁵ comprise at least three different substituents and (b) at least two of R¹, R², R³, R⁴ and R⁵ are H;
(iii) in the amidinate ligand R⁶, R⁷ and R⁸ are each a substituent independently selected from H, an unsubstituted linear C₁-C₆ alkyl group, a linear C₁-C₆ alkyl group substituted with a halogen, a linear C₁-C₆ alkyl group substituted with an amino group, an unsubstituted branched C₃-C₆ alkyl group and a branched C₃-C₆ alkyl group substituted with a halogen, a branched C₃-C₆ alkyl group substituted with an amino group, and —Si(CH₃)₃;
(iv) n=1 or 2; and
(v) the precursor is liquid below about 80° C.

2. (canceled)

3. The precursor of claim 1, wherein M is one of La, Ce, Y and Sm.

4. The precursor of claim 1, wherein M is La.

5. The precursor of claim 1, wherein M is Ce.

6. The precursor of claim 1, wherein M is Y.

7. (canceled)

8. The precursor of claim 1, wherein each cyclopentadienyl ligand is derived independently from the cycdopentadiene shown in Table 1:
TABLE 1
Cp Structure

| | |
|---|---|
| 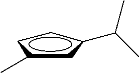 | 1A |
| 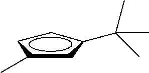 | 1B |
| 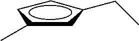 | 1C |
| 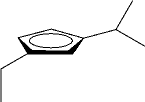 | 1D |
| 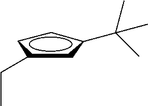 | 1E |
| 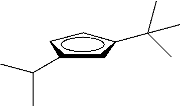 | 1F |
| 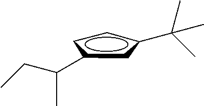 | 1G |
| 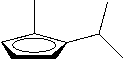 | 1H |
| 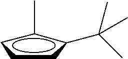 | 1I |
| 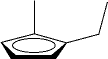 | 1J |
| 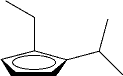 | 1K |
| 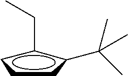 | 1L |
| 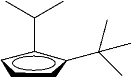 | 1M |
| 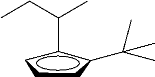 | 1N |
| 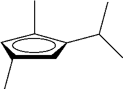 | IO |
| 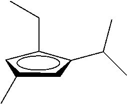 | 1P |
| 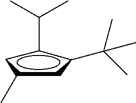 | 1Q |
| 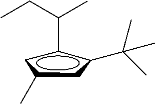 | 1R |
| 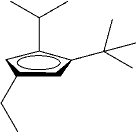 | 1S |
| 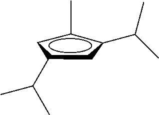 | 1T |
| 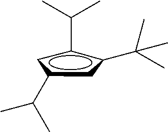 | 1U |

9. The precursor of claim 1, wherein the amidinate ligand is selected from the amidinate ligands shown in Table 2:
TABLE 2
Amidinate Structure

| | |
|---|---|
| 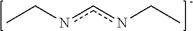 | 2A |
| 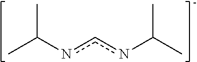 | 2B |
| 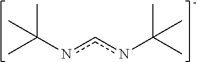 | 2C |
| 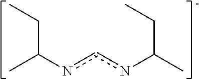 | 2D |
| 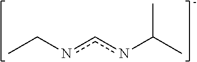 | 2E |
| 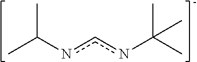 | 2F |
| 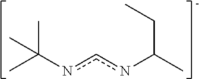 | 2G |
| 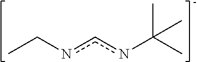 | 2H |
| 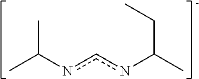 | 2I |
| 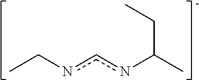 | 2J |
| 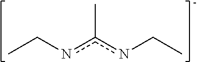 | 2K |
| 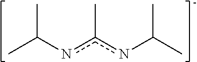 | 2L |
| 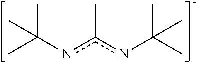 | 2M |
| 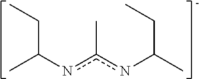 | 2N |
| 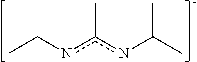 | 2O |
| 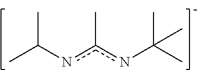 | 2P |
| 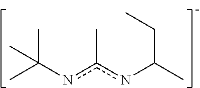 | 2Q |
| 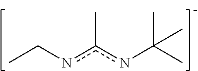 | 2R |
| 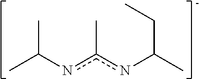 | 2S |
| 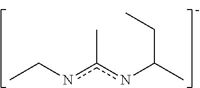 | 2T |

10. The precursor of claim 1, wherein the precursor has a structure as shown in Table 3:
TABLE 3

| Formula | Compound |
|---|---|
| (1A)₂-M-(2B) | 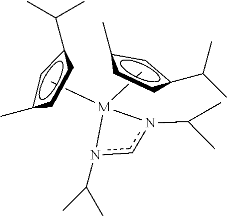 |
| (1C)₂-M-(2B) | 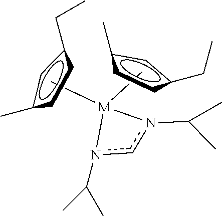 |
| (1D)₂-M-(2B) | 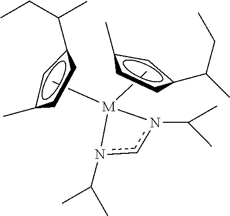 |
| (1F)₂-M-(2B) | 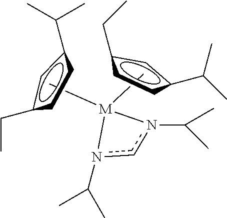 |
| (1E)₂-M-(2B) | 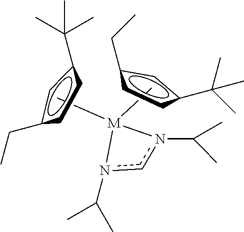 |
| (1H)₂-M-(2B) | 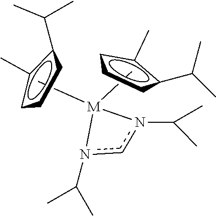 |
| (1I)₂-M-(2B) | 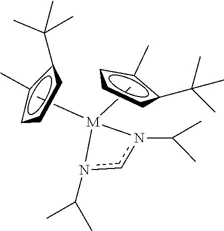 |
| (1J)₂-M-(2B) | 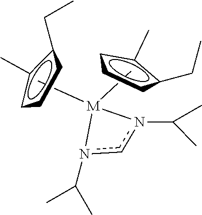 |
| (1A)₂-M-(2L) | 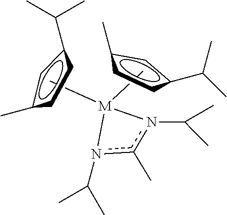 |
| (1D)₂-M-(2L) | 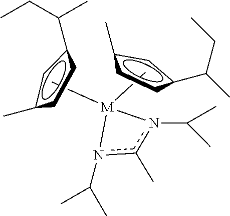 |
| (1C)₂-M-(2L) | 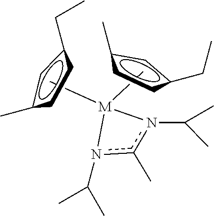 |
| (1F)₂-M-(2L) | 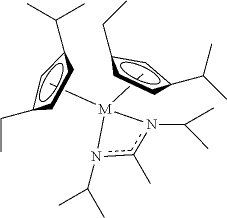 |
| (1E)₂-M-(2L) | 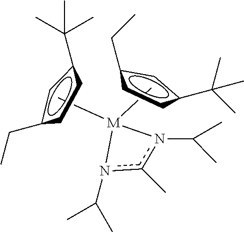 |
| (1H)₂-M-(2L) | 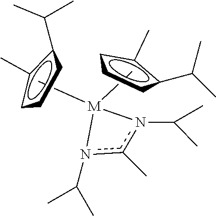 |
| (1I)₂-M-(2L) | 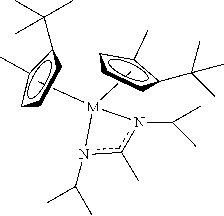 |
| (1J)₂-M-(2L) | 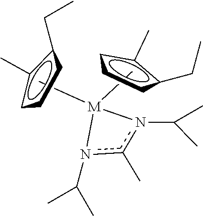 |
| (1A)₂-M-(2H) | 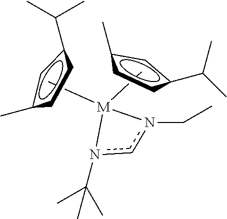 |
| (1D)₂-M-(2H) | 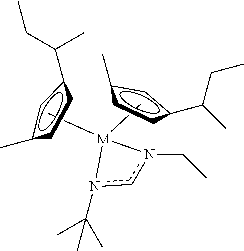 |
| (1C)₂-M-(2H) | 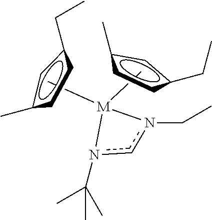 |
| (1O)₂-M-(2L) | 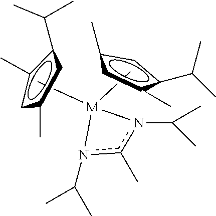 |
| (1Q)₂-M-(2B) | 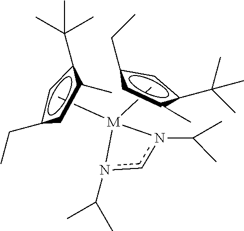 |
| (1H)₂-M-(2H) | 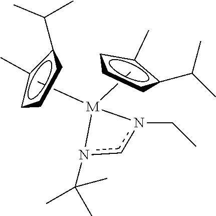 |
| (1I)₂-M-(2R) | 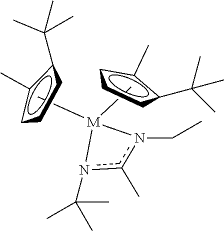 |
| (1J)₂-M-(2H) | 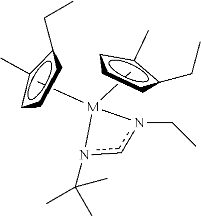 |
| (1B)₂-M-(2B) | 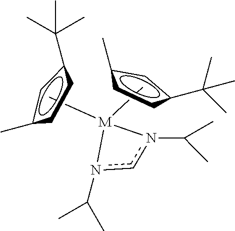 |
| (1B)₂-M-(2H) | 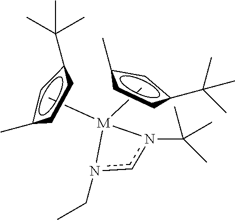 |

11. The precursor of claim 1, wherein the precursor has a structure as shown in Table 4:

| Formula | Compound |
|---|---|
| (1A)-M-(2B)₂ | 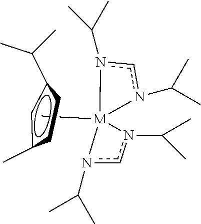 |
| (1C)-M-(2B)₂ | 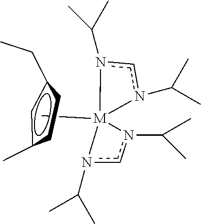 |
| (1D)-M-(2B)₂ | 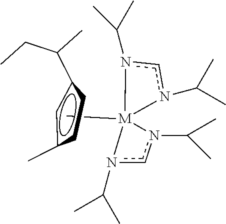 |
| (1F)-M-(2B)₂ | 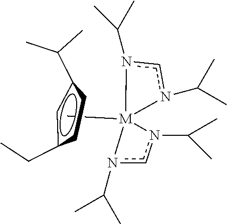 |
| (1E)-M-(2B)₂ | 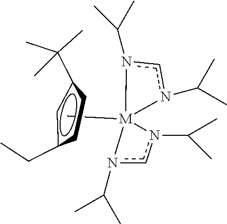 |
| (1H)-M-(2B)₂ | 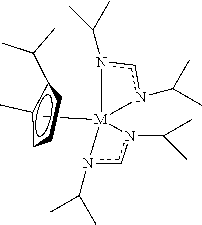 |
| (1I)-M-(2B)₂ | 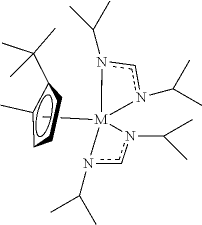 |
| (1J)-M-(2B)₂ | 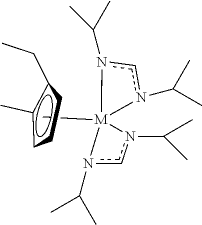 |
| (1A)-M-(2L)₂ | 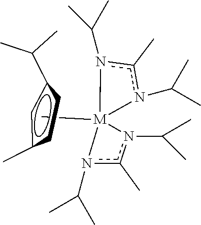 |
| (1D)-M-(2L)₂ | 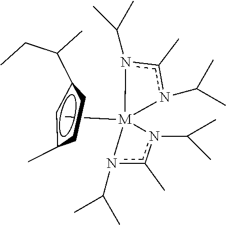 |
| (1C)-M-(2L)₂ | 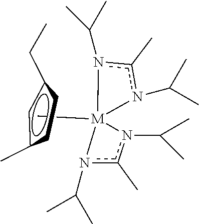 |
| (1F)-M-(2L)₂ | 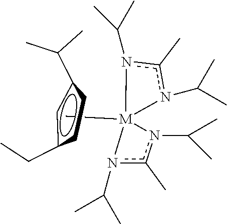 |
| (1E)-M-(2L)₂ | 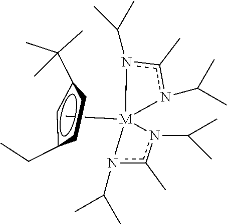 |
| (1H)-M-(2L)₂ | 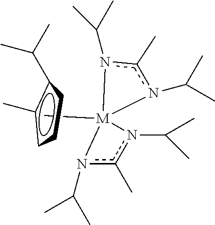 |
| (1I)-M-(2L)₂ | 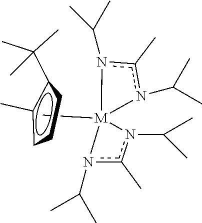 |
| (1J)-M-(2L)₂ | 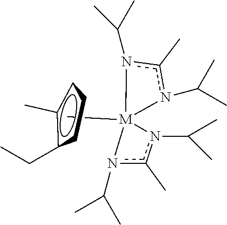 |
| (1A)-M-(2H)₂ | 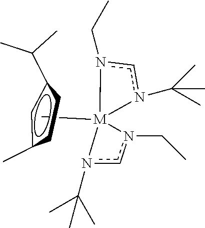 |
| (1D)-M-(2H)₂ | 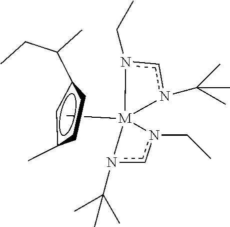 |
| (1C)-M-(2H)₂ | 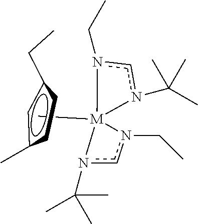 |
| (1O)-M-(2L)₂ | 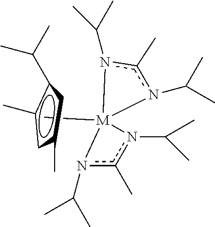 |
| (1Q)-M-(2B)₂ | 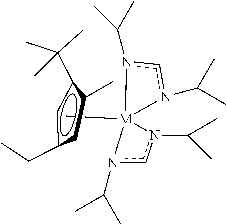 |
| (1H)-M-(2H)₂ | 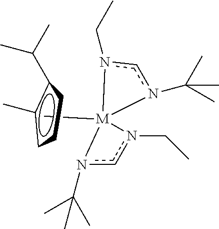 |
| (1I)-M-(2R)₂ | 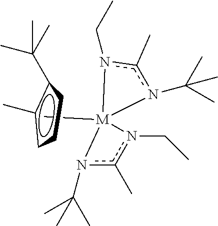 |
| (1J)-M-(2H)₂ | 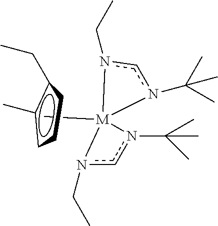 |
| (1B)-M-(2B)₂ | 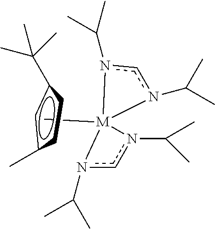 |
| (1B)-M-(2H)₂ | 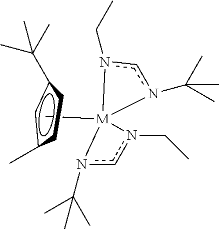 |

12-16. (canceled)

17. The precursor of claim 1, wherein R¹, R², R³, R⁴, R⁵, R⁶, R⁷ and R⁸ are each independently selected from H, an unsubstituted linear C₁-C₅ linear alkyl group and an unsubstituted branched C₃-C₆ alkyl group.

18-22. (canceled)

23. The precursor of claim 1, wherein n=1.

24. The precursor of claim 1, wherein n=2.

25-40. (canceled)

41. The precursor of claim 1 having the following structure:

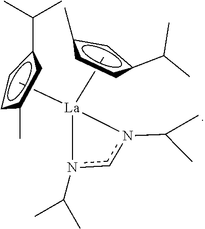

42. The precursor of claim 1 having the following structure:

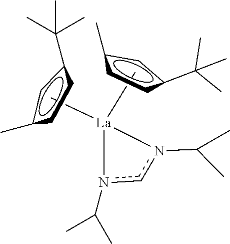

43. The precursor of claim 1 having the following structure:

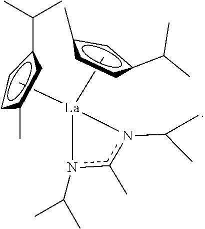

44. The precursor of claim 1 having the following structure:

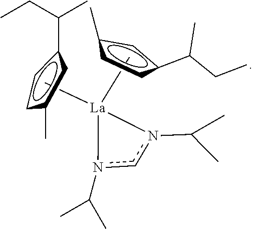

45. The precursor of claim 1 having the following structure:

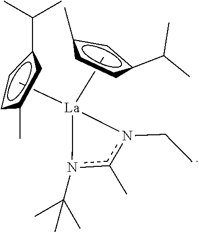

46. The precursor of claim 1 having the following structure:

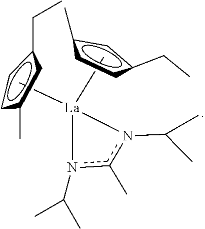

47. The precursor of claim 1 having the following structure:

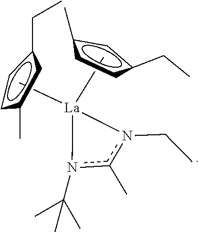

48. A method for forming a transition metal-containing film on at least one surface of a substrate comprising:
a. providing the at least one surface of the substrate in a reaction vessel;
b. forming a transition metal-containing film on the at least one surface by a deposition process chosen from a chemical vapor deposition (CVD) process and an atomic layer deposition (ALD) process using the precursor of claim 1 as a metal source compound for the deposition process.

49-58. (canceled)

59. A mixture comprising one or more precursor of claim 1 and a solvent selected from the group of toluene, mesitylene, isopropylbenzene, 4-isopropyl toluene, 1,3-diisopropylbenzene, octane, dodecane, 1,2,4-trimethylcyclohexane, n-butylcyclohexane, and decahydronaphthalene and combinations thereof.

60. (canceled)

61. (canceled)
